(19) United States
(12) Patent Application Publication
(10) Pub. No.: US 2012/0049929 A1
(43) Pub. Date: Mar. 1, 2012

(54) FIELD-EFFECT TRANSISTOR

(75) Inventor: Chih-Ta LIOU, Tu-Cheng (TW)

(73) Assignee: HON HAI PRECISION INDUSTRY CO., LTD., Tu-Cheng (TW)

(21) Appl. No.: 12/881,144

(22) Filed: Sep. 13, 2010

(30) Foreign Application Priority Data
Aug. 31, 2010 (TW) 99129376

(51) Int. Cl. H03K 17/687

(52) U.S. Cl. 327/427

(57) ABSTRACT

A field-effect transistor (FET) includes a body, a gate, a source, a drain, a capacitor, and a resistor. The gate, the source, and the drain are connected to the body. A first terminal of the capacitor is connected to the gate. A second terminal of the capacitor is connected to the source through the resistor. The body with the gate, the source, the drain, the capacitor, and the resistor are packaged together as a whole.

### BACKGROUND

1. Technical Field

The present disclosure relates to a field-effect transistor (FET).

2. Description of Related Art

In circuit design, FETs are widely used as switches. Referring to FIG. 1, a common FET 10 basically includes a body Q, a gate G, a source S, and a drain D, and sometimes further includes a diode DS connected between the source S and the drain D. FIG. 2 shows the waveform of voltage at the drain D versus time when the FET 10 is activated or turned on. If a peak value of the voltage waveform is larger than a standard value of the FET 10, the FET 10 may be damaged.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a schematic view of a common field-effect transistor (FET) including a drain.

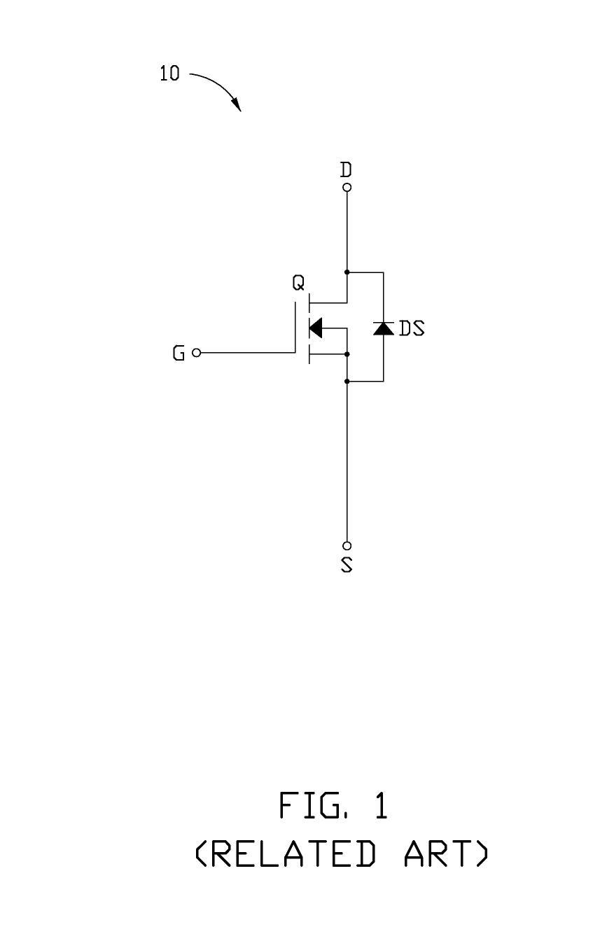

FIG. 2 is a voltage waveform chart of the drain of the EFT of FIG. 1.

FIG. 3 is a schematic view of an embodiment of an FET including a drain.

FIG. 4 is a voltage waveform chart of the drain of the EFT of FIG. 3.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

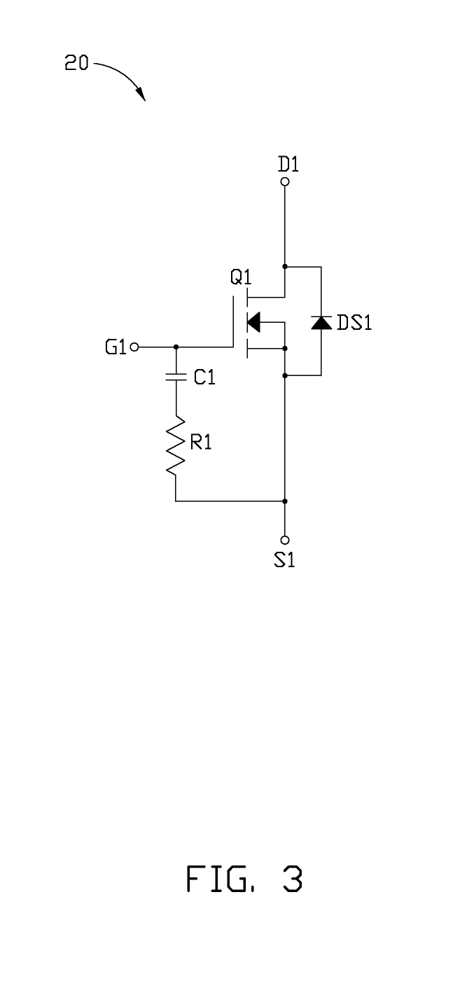

Referring to FIG. 3, an embodiment of a field-effect transistor (FET) 20 includes a body Q1, a gate G1, a source S1, a drain D1, a diode DS1, a capacitor C1, and a resistor R1. The gate G1, the source S1, and the drain D1 are connected to the body Q1. The diode DS1 is connected between the source S1 and the drain D1. It may be understood that the body Q1, the gate G1, the source S1, the drain D1, and the diode DS1 fall within well-known technologies, and are therefore not described here.

A first terminal of the capacitor C1 is connected to the gate G1. A second terminal of the capacitor C1 is connected to the source S1 through the resistor R1. The body Q1 with the gate G1, the source S1, the drain D1, the diode DS1, the capacitor C1, and the resistor R1 are packaged together as a whole.

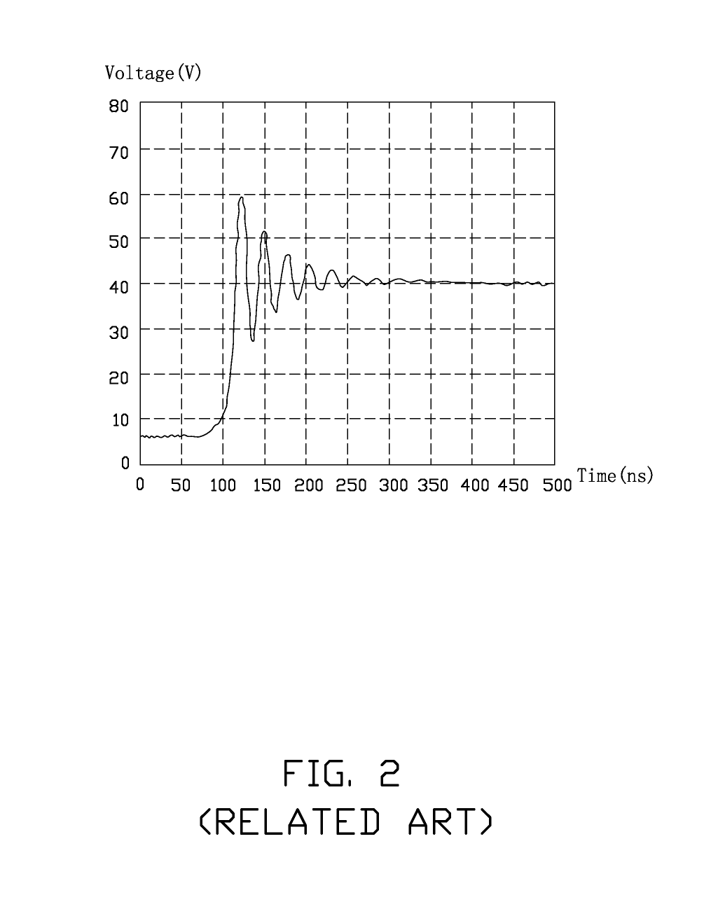

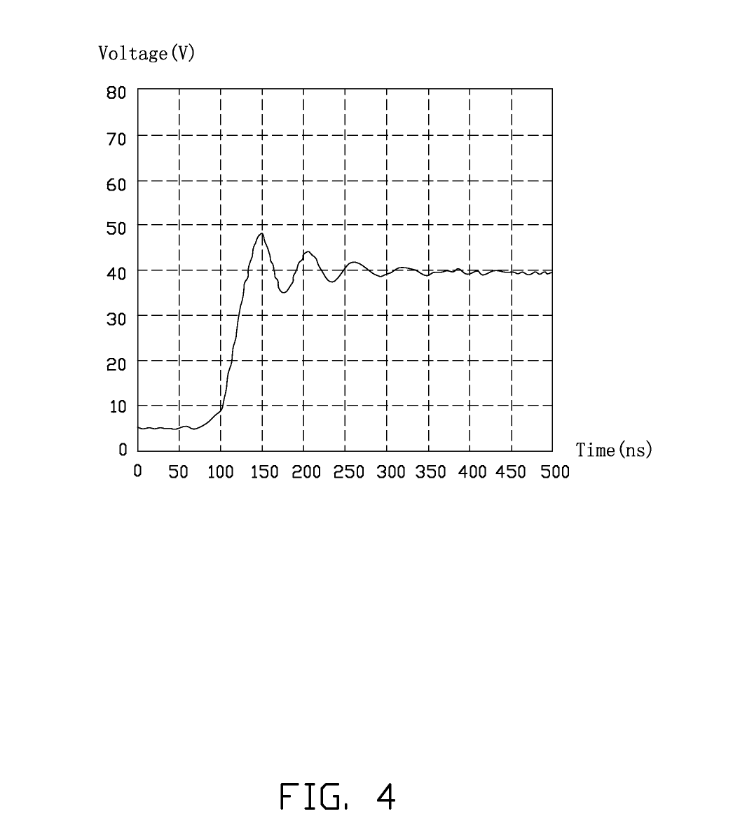

Referring to FIG. 4, when the FET 20 is included in a circuit and used under the same circumstances as those that created the waveform shown in FIG. 2, it can be clearly seen that a peak value of the voltage waveform of FIG. 4 is less than the peak value of the voltage waveform of FIG. 2. Therefore, the addition of the capacitor C1 and the resistor R1 can reduce peak voltage at the drain D1, which can prevent damage to the FET 20. Additionally, the inclusion of the capacitor C1 and the resistor R1 in the FET 20 can reduce costs over a circuit design having the capacitor and resistor separately packaged.

It is to be understood, however, that even though numerous characteristics and advantages of the embodiments have been set forth in the foregoing description, together with details of the structure and function of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A field-effect transistor (FET) comprising:
a body;
a gate, a source, and a drain connected to the body;
a capacitor; and
a resistor;
wherein a first terminal of the capacitor is connected to the gate, a second terminal of the capacitor is connected to the source through the resistor, the body with the gate, the source, the drain, the capacitor, and the resistor are packaged together as a whole.

2. The FET of claim 1, further comprising a diode connected between the source and the drain.
